(19) United States
(12) Patent Application Publication
(10) Pub. No.: US 2014/0084336 A1
(43) Pub. Date: Mar. 27, 2014

(54) SEMICONDUCTOR DEVICE

(71) Applicant: KABUSHIKI KAISHA TOSHIBA, Minato-ku (JP)

(72) Inventors: Tomoko Matsudai, Shibuya-ku (JP); Tadashi Matsuda, Kanazawa-shi (JP); Kazutoshi Nakamura, Himeji-shi (JP); Yuuichi Oshino, Tokyo (JP)

(73) Assignee: KABUSHIKI KAISHA TOSHIBA, Minato-ku (JP)

(21) Appl. No.: 14/012,824

(22) Filed: Aug. 28, 2013

(30) Foreign Application Priority Data
Sep. 24, 2012 (JP) 2012-210238

(51) Int. Cl. H01L 29/739

(52) U.S. Cl. CPC H01L 29/7393
USPC 257/140

(57) ABSTRACT

According to one embodiment, an IGBT region includes: a collector layer of a first conductivity type, a drift layer of a second conductivity type, a body layer of the first conductivity type, and a second electrode extending to the drift layer and the body layer via a first insulating film in a stacking direction of a first electrode and the collector layer. A diode region includes: a cathode layer of the second conductivity type, the drift layer, an anode layer of the first conductivity type, and a conductive layer extending to the drift layer and the anode layer via a second insulating film in the stacking direction. The second electrode and the conductive layer are separated from one another at a predetermined distance.

### CROSS-REFERENCE TO RELATED APPLICATIONS

This application is based upon and claims the benefit of priority from the prior Japanese Patent Application No. 2012-210238, filed on Sep. 24, 2012, the entire contents of which are incorporated herein by reference.

### FIELD

Embodiments described herein relate generally to a semiconductor device.

### BACKGROUND

In recent years, development of Reverse-conducting IGBT (RC-IGBT) has been popular. The RC-IGBT includes an insulated gate bipolar transistor (IGBT) and a diode that are formed on the same substrate, and have both characteristics of the IGBT and the diode.

On the other hand, conventionally, a finger structure that reduces gate resistance has been proposed in a trench IGBT. In this finger structure, gate electrodes inside trenches are extracted to a substrate surface once. Subsequently, the respective gate electrodes are connected to one another in a finger region. This reduces, for example, uneven operation due to a resistance component of the gate electrode in the same device. This also reduces deterioration in withstand voltage in an end portion of the trench disposed directly under the wiring in the finger region. Thus, a high-concentration diffusion layer is formed to cover the end portion of the trench.

Also in the case where the finger region is formed at the boundary between the IGBT and the diode in the RC-IGBT structure, the above-described diffusion layer is formed. However, the diffusion layer functions as a carrier injection source of a high-injection anode as seen from the diode. This hinders speeding up of the diode.

### BRIEF DESCRIPTION OF THE DRAWINGS

FIG. 1 is a schematic top view of a semiconductor device according to a first embodiment.

FIG. 2 is a cross-sectional view taken along line A-A′ of FIG. 1 according to the first embodiment.

FIG. 3 is a cross-sectional view taken along line B-B′ of FIG. 1 according to the first embodiment.

FIG. 4 is a cross-sectional view taken along line C-C′ of FIG. 1 according to the first embodiment.

FIG. 5 is a graph showing a relationship between: a spacing between a trench T1 and a trench T2, and an applied voltage across an anode and a cathode in a diode region R2 when pinch-off occur between the trench T1 and the trench T2.

FIG. 6 is a top view illustrating trenches T1 and T2, a gate conductive layer 18, and a conductive layer 24 according to a second embodiment.

FIG. 7 is a top view illustrating trenches T1 and T2, a gate conductive layer 18, and a conductive layer 24 according to a third embodiment.

FIG. 8 is a cross-sectional view of a semiconductor device according to another embodiment.

### DETAILED DESCRIPTION

According to one embodiment, a semiconductor device includes a first electrode, an IGBT region, and a diode region. The IGBT region includes a collector layer of a first conductivity type, a drift layer of a second conductivity type, a body layer of the first conductivity type, a second electrode, and an emitter layer of the second conductivity type. The collector layer is disposed at a first surface side of the first electrode. The drift layer is disposed at an opposite side of the collector layer with respect to the first electrode. The body layer is disposed at an opposite side of the drift layer with respect to the first electrode. The second electrode extends to the drift layer and the body layer via a first insulating film in a stacking direction of the first electrode and the collector layer. The emitter layer is in contact with the first insulating film, and disposed at an opposite side of the body layer with respect to the first electrode. The diode region includes a cathode layer of the second conductivity type, the drift layer, an anode layer of the first conductivity type, and a conductive layer. The cathode layer is disposed at the first surface side of the first electrode. The drift layer is disposed at an opposite side of t the cathode layer with respect to the first electrode. The anode layer is disposed at the opposite side of the drift layer with respect to the first electrode. The conductive layer extends to the drift layer and the anode layer via a second insulating film in the stacking direction. The second electrode and the conductive layer extend in a first direction parallel to the first surface of the first electrode. The second electrode and the conductive layer are separated from one another at a predetermined distance in the first direction.

Various embodiments will be described hereinafter with reference to the accompanying drawings.

### First Embodiment

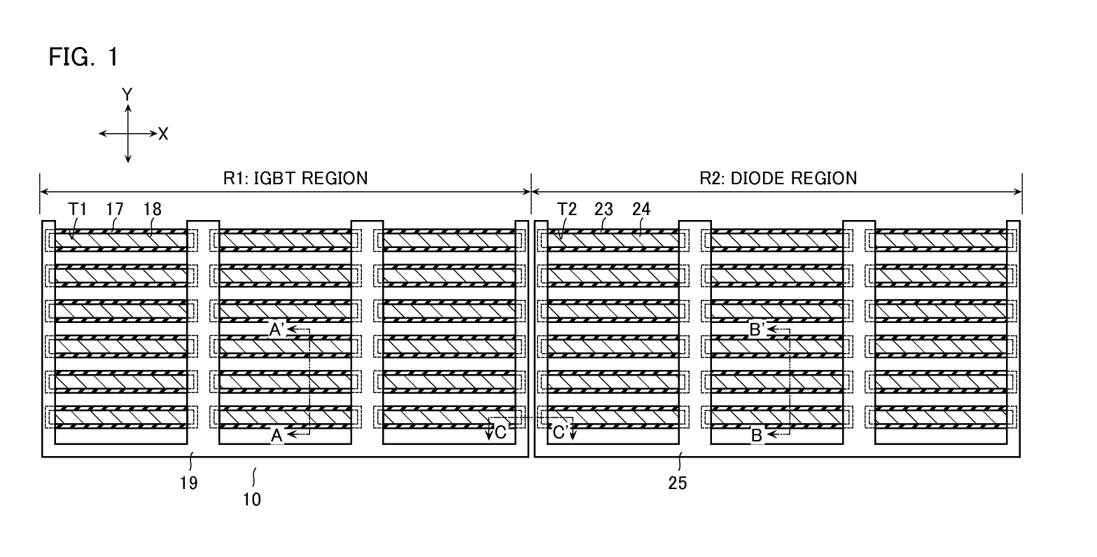

First, an overall configuration of a semiconductor device according to a first embodiment will be described with reference to FIG. 1. FIG. 1 is a schematic top view of a semiconductor device according to a first embodiment. The semiconductor device according to the first embodiment includes an IGBT region R1 and a diode region R2 on a semiconductor substrate 10 as illustrated in FIG. 1. The IGBT region R1 functions as an insulated gate bipolar transistor (IGBT). The diode region R2 is adjacent to the IGBT region R1 in the X direction, and functions as a diode. Note that the X direction is a direction parallel to the semiconductor substrate 10.

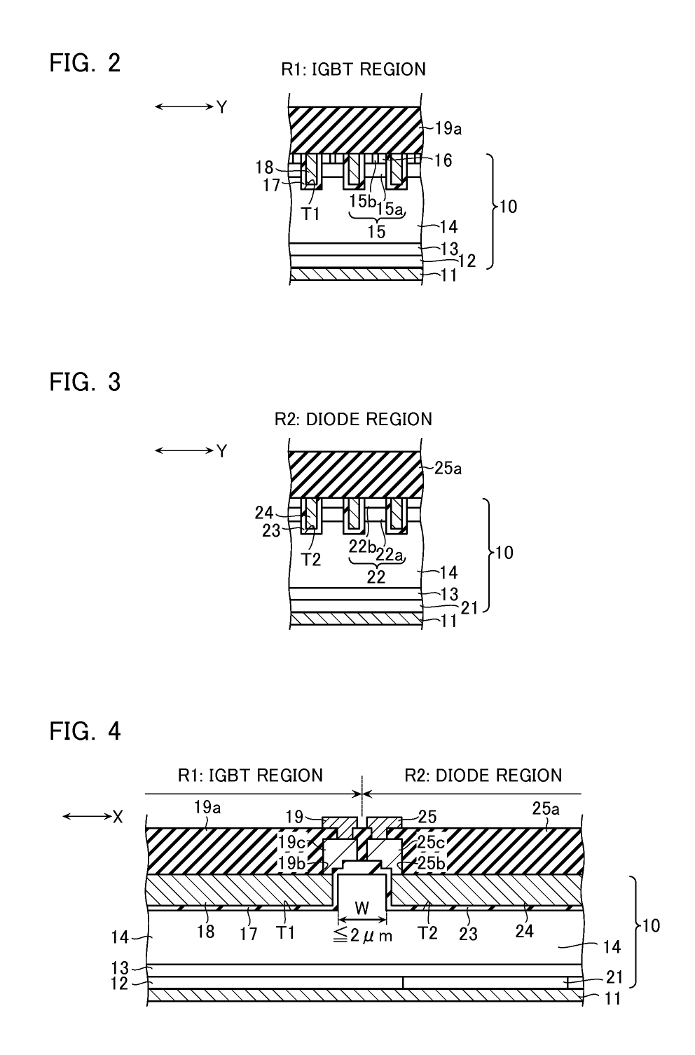

Next, the IGBT region R1 will be described with reference to FIG. 1 and FIG. 2. FIG. 2 is a cross-sectional view taken along line A-A′ of FIG. 1. The IGBT region R1 includes, as illustrated in FIG. 2, a common electrode 11, a collector layer 12, a buffer layer 13, and a drift layer 14. The common electrode 11 is disposed on a back surface of the semiconductor substrate 10. The collector layer 12 is disposed in the semiconductor substrate 10.

The common electrode 11 functions as a collector electrode of the IGBT in the IGBT region R1. The collector layer 12 functions as a collector of the IGBT. The collector layer 12 is in contact with a top surface of the common electrode 11 in the IGBT region R1. The collector layer 12 is constituted of P⁺ type semiconductor. Note that, in this embodiment below, impurity concentration of P− type semiconductor is lower than that of P type semiconductor while impurity concentration of P⁺ type semiconductor is higher than that of P type semiconductor. Similarly, impurity concentration of N⁻ type semiconductor is lower than that of N type semiconductor while impurity concentration of N⁺ type semiconductor is higher than that of N type semiconductor.

The buffer layer 13 is in contact with a top surface of the collector layer 12 in the IGBT region R1. The buffer layer 13 is constituted of N type semiconductor. The drift layer 14 is in contact with a top surface of the buffer layer 13 in the IGBT region R1. The drift layer 14 is constituted of N⁻ type semiconductor.

The IGBT region R1 includes, as illustrated in FIG. 2, a body layer 15 and an emitter layer 16 that are disposed in the semiconductor substrate 10.

The body layer 15 is in contact with a top surface of the drift layer 14 in the IGBT region R1. The body layer 15 includes a low-concentration body layer 15a and a high-concentration body layer 15b. The low-concentration body layer 15a is in contact with the top surface of the drift layer 14, and constituted of P⁻ type semiconductor. The high-concentration body layer 15b is in contact with a top surface of the low-concentration body layer 15a, and repeatedly arranged in the Y direction with a predetermined pitch. The high-concentration body layer 15b is constituted of P⁺ type semiconductor. The Y direction is a direction perpendicular to the X direction. In the body layer 15, the low-concentration body layer 15a functions as a body (a channel region) of the IGBT.

The emitter layer 16 functions as an emitter of the IGBT. The emitter layer 16 is in contact with the top surface of the low-concentration body layer 15a and a side surface of the high-concentration body layer 15b in the IGBT region R1. The emitter layer 16 is constituted of N⁺ type semiconductor.

Additionally, the IGBT region R1 includes, as illustrated in FIG. 2, a trench T1, a gate insulating layer 17, and a gate conductive layer 18.

The trench T1 is formed to recess the semiconductor substrate 10. Specifically, the trench T1 is formed to recess the drift layer 14 while penetrating through the body layer 15. As illustrated in FIG. 1, the trenches T1 each have a shape extending in the X direction, and are arranged in a matrix in the X direction and the Y direction.

The gate insulating layer 17 is formed on a surface of the trench T1. The gate insulating layer 17 is constituted of, for example, silicon oxide. The gate conductive layer 18 is buried in the trench T1 via the gate insulating layer 17, and functions as a gate of the IGBT. The gate conductive layer 18 is constituted of, for example, polysilicon.

The IGBT region R1 includes a finger wiring 19 as illustrated in FIG. 1. As illustrated in FIG. 1 and FIG. 4, the finger wiring 19 is disposed on an upper side of an end portion of the gate conductive layer 18 in the X direction via an insulating layer 19a. The finger wiring 19 electrically connects a plurality of the gate conductive layers 18 in common by a conductive layer 19c formed in a hole 19b that penetrates through the insulating layer 19a. The finger wiring 19 has a comb shape. The finger wiring 19 is formed to cover one end and another end of the adjacent gate conductive layers 18 in the X direction. In FIG. 1, the finger wiring 19 electrically connects the gate conductive layers 18 together in the IGBT region R1. For example, the finger wiring 19 may electrically connect the gate conductive layers 18 together in a terminal portion.

Next, the diode region R2 will be described with reference to FIG. 1 and FIG. 3. FIG. 3 is a cross-sectional view taken along line B-B′ of FIG. 1. The diode region R2 includes, as illustrated in FIG. 3, the common electrode 11, a cathode layer 21, the buffer layer 13, and the drift layer 14. The common electrode 11 is disposed on the back surface of the semiconductor substrate 10. The cathode layer 21, the buffer layer 13, and the drift layer 14 are disposed in the semiconductor substrate 10.

The common electrode 11 functions as a cathode electrode of the diode in the diode region R2. The common electrode 11 extends from the IGBT region R1 to the diode region R2. The cathode layer 21 functions as a cathode of the diode in the diode region R2. The cathode layer 21 is in contact with a top surface of the common electrode 11 in the diode region R2. The cathode layer 21 is constituted of N⁺ type semiconductor.

The buffer layer 13 is in contact with a top surface of the cathode layer 21 in the diode region R2. The drift layer 14 is in contact with a top surface of the buffer layer 13 in the diode region R2. The buffer layer 13 and the drift layer 14 each extend from the IGBT region R1 to the diode region R2.

The diode region R2 includes, as illustrated in FIG. 3, an anode layer 22, a trench T2, an insulating layer 23, and a conductive layer 24.

The anode layer 22 functions as an anode of the diode. The anode layer 22 is in contact with a top surface of the drift layer 14 in the diode region R2. The anode layer 22 includes a low-concentration anode layer 22a and a high-concentration anode layer 22b. The low-concentration anode layer 22a is in contact with the top surface of the drift layer 14, and constituted of P⁻ type semiconductor. The high-concentration anode layer 22b is in contact with a top surface of the low-concentration anode layer 22a, and constituted of P⁺ type semiconductor.

The trench T2 is formed to recess the semiconductor substrate 10. Specifically, the trench T2 is formed to recess the drift layer 14 while penetrating through the anode layer 22. As illustrated in FIG. 1, the trenches T2 each have a shape extending in the X direction, and are arranged in a matrix in the X direction and the Y direction.

The insulating layer 23 is formed on a surface of the trench T2. The insulating layer 23 is constituted of, for example, silicon oxide. The conductive layer 24 is buried in the trench T2 via the insulating layer 23, and functions as an anode electrode of the diode. The conductive layer 24 is constituted of, for example, polysilicon.

The diode region R2 includes a finger wiring 25 as illustrated in FIG. 1. The finger wiring 25 is disposed on an upper side of an end portion of the conductive layer 24 in the X direction via an insulating layer 25a as illustrated in FIG. 1 and FIG. 4. The finger wiring 25 electrically connects a plurality of conductive layers 24 in common by a conductive layer 25c formed in a hole 25b that penetrates through the insulating layer 25a. The finger wiring 25 has a comb shape. The finger wiring 25 is formed to cover one end and another end of the adjacent conductive layers 24 in the X direction. Note that the finger wiring 19 and the finger wiring 25 are insulated and separated from one another. Note that the gate conductive layer 18 in the IGBT region R1 functions as a gate, and the conductive layer 24 in the diode region R2 functions as an anode. Therefore, the gate conductive layer 18 and the conductive layer 24 are not connected together in the IGBT region R1 or the diode region R2.

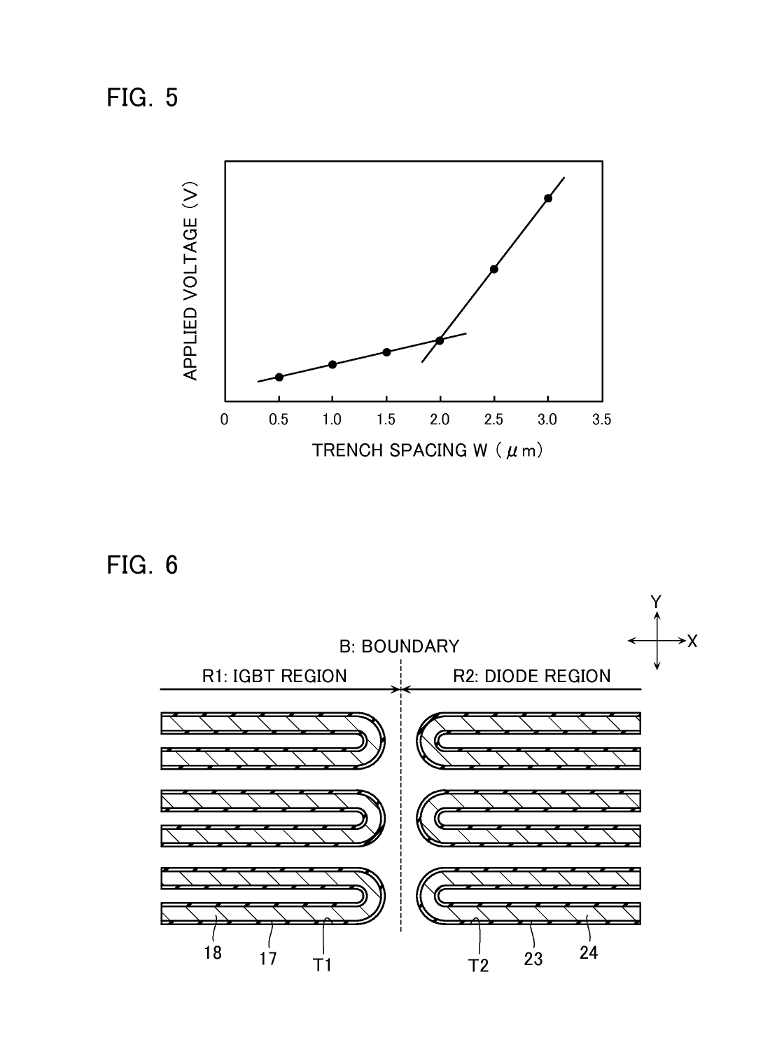

Next, a spacing (hereinafter referred to as a trench spacing W) between the trench T1 (the gate conductive layer 18) and the trench T2 (the conductive layer 24) will be described with reference to FIG. 4. FIG. 4 is a cross-sectional view taken along line C-C′ of FIG. 1. In one example illustrated in FIG. 4, the trench spacing W is set equal to or less than 2 μm. This trench spacing W is set based on a relationship shown in FIG. 5 below.

The horizontal axis in FIG. 5 indicates the trench spacing W (μm). In case of the RC-IGBT, the body layer 15 of the IGBT and the anode layer 22 of the diode are connected together in a diffusion layer at the same electric potential. Accordingly, in the case where a reverse bias is applied across: the body layer 15 and/or the anode layer 22, and the drift layer 14 and then a depletion layer extends therefrom, an applied voltage (V) when pinch-off occurs between the trench T1 and the trench T2 is shown. As illustrated in FIG. 5, in the case where the trench spacing W is equal to or less than 2 μm, the applied voltage becomes higher at a first increasing rate in association with expansion of the trench spacing W. As illustrated in FIG. 5, in the case where the trench spacing W is larger than 2 μm, the applied voltage becomes higher at a second increasing rate that is higher than the first increasing rate in association with expansion of the trench spacing W. This shows that the trench spacing W equal to or less than 2 μm is preferred to have pinch-off between the trench T1 and the trench T2 with a small applied voltage. Therefore, in this embodiment, the trench spacing W is set equal to or less than 2 μm as one example illustrated in FIG. 4. This embodiment allows a pinch-off state between the trench T1 and the trench T2 even in the case where the applied voltage is small. Accordingly, this embodiment maintains a high static withstand voltage without countermeasure against deterioration in withstand voltage at the trench tip by forming a high-concentration diffusion layer between the trench T1 and the trench T2.

In the example illustrated in FIG. 4, the trench spacing W is set equal to or less than 2 μm. However, a trench spacing where the increasing rate of the applied voltage varies rapidly has a value different from 2 μm depending on concentration of each layer, a trench depth, and similar parameter. Therefore, the trench spacing W according to this embodiment may be any trench spacing equal to or less than a trench spacing (at an inflection point) where the increasing rate of the applied voltage varies.

In the diode region R2 according to this embodiment, in the case where a sidewall-to-sidewall spacing between the adjacent conductive layers 24 (the trenches T2) in the Y direction is A and a depth of the conductive layer 24 (the trench T2) is B, it is preferred that A/B≦0.5 be satisfied. Under this condition, the drift layer 14 below the low-concentration anode layer 22a becomes a depletion layer between the adjacent conductive layers 24. This prevents the depletion layer in the low-concentration anode layer 22a from reaching the upper layer.

### Second Embodiment

Next, a semiconductor device according to a second embodiment will be described with reference to FIG. 6. FIG. 6 is a top view illustrating trenches T1 and T2, a gate conductive layer 18, and a conductive layer 24 according to a second embodiment. Here, the finger wiring is not especially illustrated. As illustrated in FIG. 6, in the second embodiment, the trenches T1 and T2 each extend in the X direction and have a U shape folded back at the boundary B between the IGBT region R1 and the diode region R2. Therefore, similarly, the gate conductive layer 18 and the conductive layer 24 each extend in the X direction and have a U shape folded back at the boundary B between the IGBT region R1 and the diode region R2. The second embodiment differs from the first embodiment only in this point. The second embodiment is otherwise similar to the first embodiment, and provides advantageous effects similar to those of the first embodiment.

### Third Embodiment

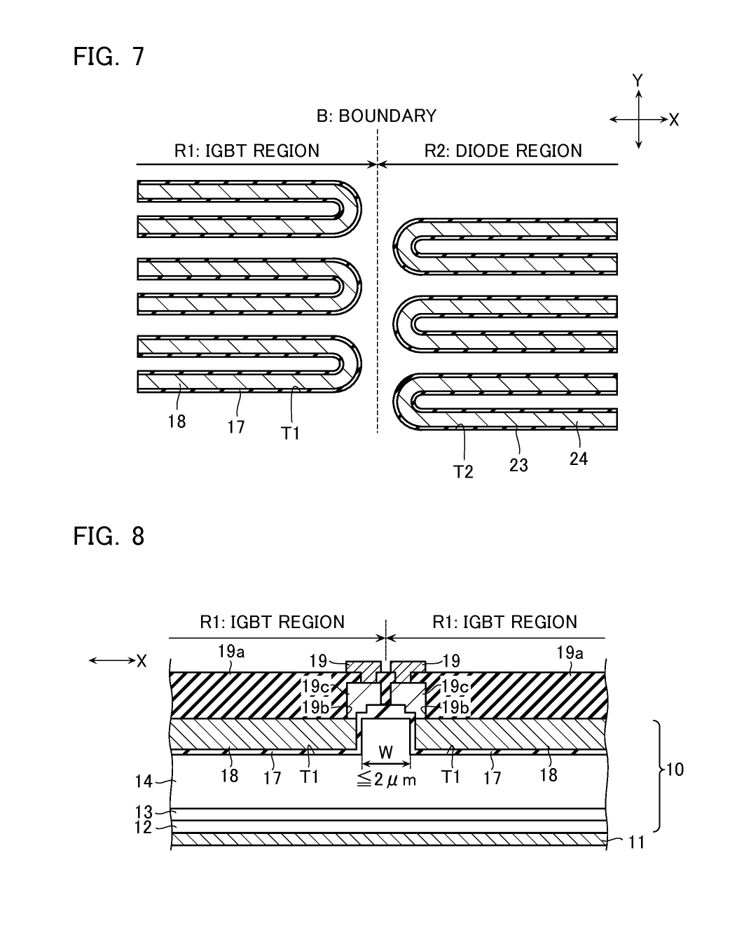

Next, a semiconductor device according to a third embodiment will be described with reference to FIG. 7. FIG. 7 is a top view illustrating trenches T1 and T2, a gate conductive layer 18, and a conductive layer 24 according to a third embodiment. Here, the finger wiring is not especially illustrated. As illustrated in FIG. 7, in the third embodiment, the trenches T1 and T2, the gate conductive layer 18, and the conductive layer 24 each have a U shape similarly to the second embodiment. On the other hand, in the third embodiment, the trenches T1 and T2 are not arranged in a straight row in the X direction, and are offset from one another in the Y direction. Therefore, similarly, the gate conductive layer 18 and the conductive layer 24 are not arranged in a straight row in the X direction, and are offset from one another in the Y direction. The third embodiment differs from the first and second embodiments only in this point. The third embodiment is otherwise similar to the first embodiment, and provides advantageous effects similar to those of the first embodiment.

### Another Embodiment

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the above-described structures according to the first to third embodiments are applied to one IGBT region R1 and one diode region R2 that are adjacent to one another. However, as illustrated in FIG. 8, these embodiments are applicable to two adjacent IGBT regions R1. The two IGBT regions R1 illustrated in FIG. 8 has a stacked structure similar to that of the first embodiment. The gate conductive layers 18 each extend in the X direction, and are separated from one another by the trench spacing W in the X direction. Note that the structure illustrated in FIG. 8 is not limited to the first embodiment, and applicable to the second and the third embodiment.

What is claimed is:

1. A semiconductor device comprising:
a first electrode;
an IGBT region including: a collector layer of a first conductivity type disposed at a first surface side of the first electrode; a drift layer of a second conductivity type disposed at an opposite side of the collector layer with respect to the first electrode; a body layer of the first conductivity type disposed at an opposite side of the drift layer with respect to the first electrode; a second electrode extending in the drift layer and the body layer via a first insulating film in a stacking direction of the first electrode and the collector layer; and an emitter layer of the second conductivity type in contact with the first insulating film, the emitter layer being disposed at an opposite side of the body layer with respect to the first electrode; and
a diode region including: a cathode layer of the second conductivity type disposed at the first surface side of the first electrode; the drift layer disposed at the opposite side of the cathode layer with respect to the first electrode; an anode layer of the first conductivity type disposed at the opposite side of the drift layer with respect to the first electrode; and a conductive layer extending to the drift layer and the anode layer via a second insulating film in the stacking direction, wherein
the second electrode and the conductive layer extend in a first direction parallel to the first surface of the first electrode,
the second electrode and the conductive layer are separated from one another at a predetermined distance in the first direction.

2. The semiconductor device according to claim 1, wherein the predetermined distance is equal to or less than 2 μm.

3. The semiconductor device according to claim 1, wherein
the second electrode extends in the first direction and has a U shape folded back at a boundary between the IGBT region and the diode region.

4. The semiconductor device according to claim 1, wherein
the conductive layer extends in the first direction and has a U shape folded back at a boundary between the IGBT region and the diode region.

5. The semiconductor device according to claim 1, wherein
the second electrode and the conductive layer are arranged in one row in a second direction perpendicular to the first direction.

6. The semiconductor device according to claim 1, wherein
the second electrode and the conductive layer are offset from one another in a second direction perpendicular to the first direction.

7. The semiconductor device according to claim 1, wherein
in a case where an electrode spacing between the second electrode and the conductive layer is equal to or less than a first spacing, expansion of the electrode spacing increases an applied voltage across the anode layer and the drift layer in the diode region when pinch-off occurs between the second electrode and conductive layer at a first increasing rate,
in a case where the electrode spacing is larger than the first spacing, expansion of the electrode spacing increases the applied voltage at a second increasing rate that is higher than the first increasing rate, and
the electrode spacing is set equal to or less than the first spacing.

8. The semiconductor device according to claim 1, wherein
a plurality of the second electrodes and a plurality of the conductive layers are arranged at a second spacing in the first direction and a second direction, the second direction being parallel to the first surface of the first electrode and perpendicular to the first direction.

9. The semiconductor device according to claim 1, further comprising:
a first wiring disposed at an opposite side of the second electrode with respect to the first electrode, the first wiring electrically connecting a plurality of the second electrodes; and
a second wiring disposed at an opposite side of the conductive layer with respect to the first electrode, the second wiring electrically connecting a plurality of the conductive layers, wherein
the first wiring is formed to cover one end and another end of the second electrodes adjacent to one another in the first direction,
the second wiring is formed to cover one end and another end of the conductive layers adjacent to one another in the first direction, and
the first wiring and the second wiring are insulated and separated from one another.

10. The semiconductor device according to claim 1, wherein
in a case where a sidewall-to-sidewall spacing between a pair of the conductive layers is A and a depth of the conductive layer in the stacking direction is B, a ratio of A to B is equal to or less than 0.5.

11. The semiconductor device according to claim 1, wherein
the body layer includes:
a first body layer in contact with the drift layer; and
a second body layer in contact with the first body layer, the second body layer having a higher impurity concentration than an impurity concentration of the first body layer.

12. The semiconductor device according to claim 1, wherein
the anode layer includes:
a first anode layer in contact with the drift layer; and
a second anode layer in contact with the first body layer, the second anode layer having a higher impurity concentration than an impurity concentration of the first anode layer.

13. The semiconductor device according to claim 9, wherein
the first wiring has a comb shape.

14. The semiconductor device according to claim 9, wherein
the second wiring has a comb shape.

15. The semiconductor device according to claim 9, further comprising:
a first insulating layer disposed at the opposite side of the second electrode with respect to the first electrode; and
a first conductive layer disposed in the first insulating layer, wherein
the first wiring is electrically connected to the second electrode via the first conductive layer.

16. The semiconductor device according to claim 9, further comprising:
a second insulating layer disposed at the opposite side of the conductive layer with respect to the first electrode; and
a second conductive layer disposed in the second insulating layer, wherein
the second wiring is electrically connected to the conductive layer via the second conductive layer.

17. The semiconductor device according to claim 1, wherein
the first insulating film is constituted of silicon oxide, and
the second electrode is constituted of polysilicon.

18. The semiconductor device according to claim 1, wherein
the second insulating film is constituted of silicon oxide, and
the conductive layer is constituted of polysilicon.

19. The semiconductor device according to claim 1, wherein
in a case where an electrode spacing between the second electrode and the conductive layer is equal to or less than a first spacing, expansion of the electrode spacing increases an applied voltage across the body layer and the drift layer in the IGBT region when pinch-off occurs between the second electrode and conductive layer at a first increasing rate,
in a case where the electrode spacing is larger than the first spacing, expansion of the electrode spacing increases the applied voltage at a second increasing rate that is higher than the first increasing rate, and
the electrode spacing is set equal to or less than the first spacing.

20. A semiconductor device comprising:
a first electrode; and
a first IGBT region and a second IGBT region including:
a collector layer of a first conductivity type disposed at a first surface side of the first electrode; a drift layer of a second conductivity type disposed at an opposite side of the collector layer with respect to the first electrode;
a body layer of the first conductivity type disposed at an opposite side of the drift layer with respect to the first electrode; a second electrode extending in the drift layer and the body layer via a first insulating film in a stacking direction of the first electrode and the collector layer; and
an emitter layer of the second conductivity type in contact with the first insulating film, the emitter layer being disposed at an opposite side of the body layer with respect to the first electrode, wherein
a plurality of the second electrodes extend in a first direction parallel to the first surface of the first electrode, and
the plurality of second electrodes are separated from one another at a predetermined distance in the first direction.
